(19) United States
(12) Patent Application Publication
(10) Pub. No.: US 2008/0315964 A1
(43) Pub. Date: Dec. 25, 2008

(54) Voltage controlled oscillator using tunable active inductor

(75) Inventor: Su Tae Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 12/213,525

(22) Filed: Jun. 20, 2008

(30) Foreign Application Priority Data
Jun. 22, 2007 (KR) 10-2007-0061731

(51) Int. Cl. H03B 7/06; H03H 11/48

(52) U.S. Cl. 331/115; 333/217

(57) ABSTRACT

A tunable active inductor and a voltage controlled oscillator (VCO) are provided. The tunable active inductor includes a first current source coupled to a power source, a first metal-oxide semiconductor (MOS) transistor including a drain coupled to the first current source and a gate coupled to a first bias voltage, a second MOS transistor including a drain coupled to the power source and a gate coupled to the drain of the first MOS transistor, the gate of the second MOS and the drain of the first MOS being coupled to a second bias voltage, a resonator coupled to a source of the second MOS transistor, and a second current source coupled to the resonator. The VCO employs the tunable active inductor to freely vary the oscillation range of the VCO in a high frequency band.

### RELATED APPLICATION

This application claims the benefit of priority to Korean Patent Application No. 10-2007-0061731, filed on Jun. 22, 2007, the entire contents of which are incorporated herein by reference.

### TECHNICAL FIELD

The present invention relates to a voltage controlled oscillator, and more particularly, to a P-tail (parallel tail) p-core voltage controlled oscillator, which may be formed without using a block capacitor. The voltage controlled oscillator may use a P-tail current source to lower a direct current (DC) voltage of a node connected to a tunable active inductor of the voltage controlled oscillator.

### BACKGROUND

In general, a voltage controlled oscillator (VCO) is a device for outputting a desired oscillation frequency in accordance with a voltage applied to the VCO. The VCO may improve the efficiency and stability of signal processing when modulating or demodulating a radio frequency (RF) signal.

The VCO typically varies its output oscillation frequency by using a variable capacitance diode (hereinafter, referred to as a “varactor diode” or a “varactor”), the capacitance of which can be varied according to an input voltage applied to the varactor diode.

FIG. 1 is a block diagram illustrating a configuration of a conventional VCO. The VCO may include a resonance stage 100, an amplification stage 102, and an optional output matching stage 104, which performs a matching operation according to a predetermined function. To operate as an oscillator, the VCO should at least include amplification stage 102, which is an active element area, and resonance stage 100, which is a passive element area. An oscillation can be induced by a positive feedback circuit contained in resonance stage 100 and/or amplification stage 102. The capacitance of the positive feedback circuit is changed by adjusting a voltage applied to the varactor diode in resonance stage 100. The VOC can thus vary its output frequency.

However, when varying an oscillation frequency using a varactor diode in a high frequency band of, for example, 5 GHz or more, a parasitic capacitance of an active circuit used for generating negative resistance may become very large. Accordingly, as a result of the large parasitic capacitance of the active circuit, the capacitance of a resonant circuit may become very small.

Because the capacitance varied by the varactor diode is included in the parasitic capacitance, it is difficult to vary an oscillation frequency in a high frequency band.

### SUMMARY

In one embodiment consistent with the present invention, there is provided a tunable active inductor including a first current source coupled to a power source, a first metal-oxide semiconductor (MOS) transistor including a drain coupled to the first current source and a gate coupled to a first bias voltage, a second MOS transistor including a drain coupled to the power source and a gate coupled to the drain of the first MOS transistor, the gate of the second MOS and the drain of the first MOS being coupled to a second bias voltage, a resonator coupled to a source of the second MOS transistor, and a second current source coupled to the resonator.

In another embodiment consistent with the present invention, there is provided a VCO including a constant current source, a negative resistance generator comprising first and second transistors to output an oscillation frequency according to a current supplied from the constant current source, and a tunable active inductor coupled to the negative resistance generator.

### BRIEF DESCRIPTION OF THE DRAWINGS

The above and other features consistent with the present invention will become apparent from the following description of embodiments given in conjunction with the accompanying drawings, in which:

FIG. 1 is a block diagram illustrating a configuration of a conventional VCO;

FIG. 2 is a circuit diagram of a tunable active inductor according to an embodiment consistent with the present invention; and

FIG. 3 is a circuit diagram of a P-tail p-core VCO using a tunable active inductor according to an embodiment consistent with the present invention.

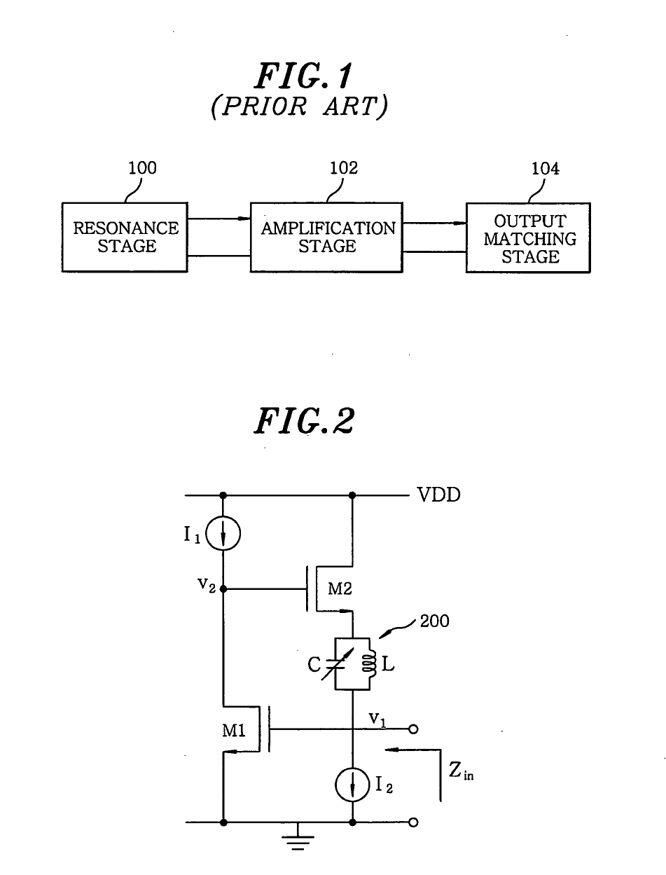

### DETAILED DESCRIPTION

Hereinafter, embodiments consistent with the present invention will be described in detail with reference to the accompanying drawings so that they can be readily implemented by those skilled in the art.

FIG. 2 is a circuit diagram of a tunable active inductor according to an embodiment consistent with the present invention.

As shown in FIG. 2, the tunable active inductor may include a bias current source I1, one end of which is connected to a power source VDD; a first MOS transistor M1 having a drain connected to the other end of bias current source I1, a gate connected to a bias voltage terminal V1, and a source connected to the ground; a second MOS transistor M2 having a drain connected to power source VDD and a gate connected to the drain of first MOS transistor M1, the gate of second MOS M2 having a reference voltage V2; a resonator 200 connected to second MOS transistor M2 to generate a oscillation frequency; and a second current source I2, one end of which is connected to resonator 200 and the other end of which is connected to the ground. In one embodiment, resonator 200 may include an LC resonator 200 having a variable capacitor C and an inductor L coupled in parallel with capacitor C.

Bias current sources I1 and I2 may be implemented by PMOS and NMOS current sources, respectively (not shown). If the control voltages to the PMOS and NMOS current sources are adjusted, the voltage status of first and second transistors M1 and M2 may be changed to vary transconductance gₘ of first and second transistors M1 and M2, which may change the inductance of the tunable active inductor. That is, the frequency representing the highest quality factor (Q-factor) decreases if the control voltage of the PMOS current source is adjusted to increase the inductance of the tunable active inductor. On the other hand, the frequency representing the highest Q-factor increases if the control voltage of the NMOS is adjusted to increase the inductance of the tunable active inductor. This means that adjusting the control voltages of the PMOS and NMOS current sources may vary both the frequency representing the highest Q-factor and the inductance of the tunable active inductor.

Accordingly, the tunable active inductor may be embodied with an inductor having a high Q-factor in a high frequency range. A high Q-factor in an inductor is an essential element for reducing phase noise of the VCO. As will be discussed below, an oscillation frequency of a voltage controlled oscillator (VCO) can be stably changed even in a high frequency range by using the tunable active inductor having a high Q-factor that can stably control the phase noise of the VCO to a predetermined level or less. That is, as shown in FIG. 2, the tunable active inductor consistent with the present invention may be embodied with an inductor L having a high Q-factor in a high frequency range, thereby showing characteristics different from a passive element that does not represent inductance in a high frequency due to a low self-resonant frequency (SRF). Further, because the tunable active inductor can vary the frequency range and the inductance representing the highest Q-factor, an operation range thereof may be very wide.

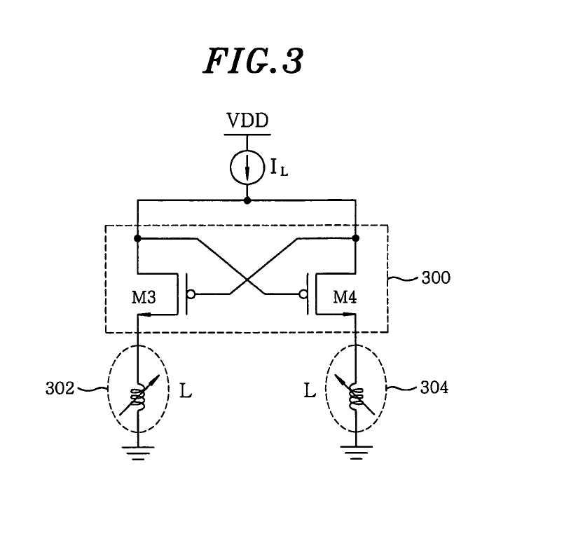

Referring now to FIG. 3, there is illustrated a circuit diagram of a P-tail p-core VCO using a tunable active inductor according to an embodiment consistent with the present invention.

As shown in FIG. 3, the P-tail p-core VCO may include a constant current source I_{L} for supplying a predetermined current and a negative resistance generator 300, which may output an oscillation frequency according to the current supplied from constant current source I_{L}. In one embodiment, negative resistance generator 300 may include third and fourth MOS transistors M3 and M4 for sustaining an oscillation of the VCO. In one embodiment, third and fourth MOS transistors M3 and M4 may be PMOS transistors. As shown in FIG. 3, the drains of third and fourth MOS transistors M3 and M4 are connected to constant current source I_{L}. Further, the gate of third MOS transistor M3 is connected to the drain of fourth MOS transistor, and the gate of fourth MOS transistor M4 is connected to the drain of third MOS transistor M3. By respectively connecting one end of variable inductors 302 and 304 to the sources of third and fourth transistors M3 and M4 of negative resistance generator 300 and connecting the other end of variable inductors 302 and 304 to ground, the oscillation frequency range of the VCO can be widened. In one embodiment, variable inductors 302 and 304 may be the tunable active inductor discussed above and illustrated in FIG. 2, and may be used to vary the frequency representing a high Q-factor that can control the phase noise of the VCO to a predetermined level or less.

In this case, in the P-tail VCO, by lowering a DC voltage of a node connected to the tunable active inductor using the P-tail current source as constant current source I_{L}, the VCO can be realized without using a block capacitor.

While the present invention has been shown and described with respect to various embodiments, it will be understood by those skilled in the art that various changes and modifications may be made without departing from the scope of the following claims.

What is claimed is:

1. A tunable active inductor, comprising:
a first current source coupled to a power source;
a first metal-oxide semiconductor (MOS) transistor including a drain coupled to the first current source and a gate coupled to a first bias voltage;
a second MOS transistor including a drain coupled to the power source and a gate coupled to the drain of the first MOS transistor, the gate of the second MOS transistor and the drain of the first MOS transistor being coupled to a second bias voltage;
a resonator coupled to a source of the second MOS transistor; and
a second current source coupled to the resonator.

2. The tunable active inductor of claim 1, wherein the tunable active inductor comprises a variable inductance which is varied by adjusting the first and second bias voltages.

3. The tunable active inductor of claim 1, wherein the tunable active inductor has a high quality factor at a high frequency band.

4. The tunable active inductor of claim 1, wherein the resonator comprises a variable capacitor and an inductor coupled with the variable capacitor in parallel.

5. A voltage controlled oscillator, comprising:
a constant current source;
a negative resistance generator comprising first and second transistors to output an oscillation frequency according to a current supplied from the constant current source; and
a tunable active inductor coupled to the negative resistance generator.

6. The voltage controlled oscillator of claim 5, wherein the tunable active inductor comprises:
a first current source coupled to a power source;
a third transistor including a drain coupled to the first current source and a gate coupled to a first bias voltage;
a fourth transistor including a drain coupled to the power source and a gate coupled to the drain of the third transistor, the gate of the fourth transistor and the drain of the third transistor being coupled to a second bias voltage;
a resonator coupled to a source of the fourth transistor; and
a second current source coupled to the resonator.

7. The voltage controlled oscillator of claim 6, wherein the tunable active inductor comprises a variable inductance which is varied by adjusting the first and second bias voltages.

8. The voltage controlled oscillator of claim 5, wherein the constant current source comprises a P-tail (Parallel-tail) current source.

9. The voltage controlled oscillator of claim 8, wherein the P-tail current source lowers a DC voltage at an input node of the tunable active inductor to a predetermined reference level or less.

10. The voltage controlled oscillator of claim 5, wherein the tunable active inductor includes a first variable inductor and a second variable inductor.

11. The voltage controlled oscillator of claim 10, wherein the first variable inductor is coupled to the first transistor and the second variable inductor is coupled to the second transistor.

12. The voltage controlled oscillator of claim 5, wherein a gate of the first transistor is coupled to a drain of the second transistor, and a gate of the second transistor is coupled to a drain of the first transistor.

13. The voltage controlled oscillator of claim 6, wherein the first transistor comprises a first PMOS transistor, the second transistor comprises a second PMOS transistor, the third transistor comprises a first MOS transistor, and the fourth transistor comprises a second MOS transistor.
